(19) United States
(12) Patent Application Publication
(10) Pub. No.: US 2026/0255949 A1
(43) Pub. Date: Aug. 27, 2026

(54) WIRING SUBSTRATE AND PREPARATION METHOD THEREFOR, AND DISPLAY APPARATUS

(71) Applicants: Hefei BOE Ruisheng Technology Co., Ltd., Anhui (CN); BOE Technology Group Co., Ltd., Beijing (CN)

(72) Inventors: Jie LEI, Beijing (CN); Yajun MA, Beijing (CN); Jian TIAN, Beijing (CN); Chunjian LIU, Beijing (CN); Jianying ZHANG, Beijing (CN)

(21) Appl. No.: 18/993,868

(22) PCT Filed: May 14, 2024
(86) PCT No.: PCT/CN2024/093221

§ 371 Date: Jan. 13, 2025

(30) Foreign Application Priority Data
Jun. 29, 2023 (CN) 202310787059.9

(51) Int. Cl. H10W 20/41; H10W 20/00; H10W 20/43

(52) U.S. Cl. CPC H10W 20/425; H10W 20/063; H10W 20/43

(57) ABSTRACT

Disclosed in the present disclosure are a wiring substrate and a preparation method therefor, and a display apparatus. A wiring substrate provided in the embodiments of the present disclosure, the wiring substrate comprising: a base substrate, which comprises a fan-out area; a plurality of first electrodes, which are located on one side of the base substrate; and a first protective layer, which is located on the side of the plurality of first electrodes away from the base substrate and comprises a plurality of first openings penetrating the thickness of the first protective layer, wherein each first opening among the plurality of first openings corresponds to one first electrode, the orthographic projection of said first opening on the base substrate overlaps the orthographic projection of the first electrode on the base substrate; the first protective layer covers at least the side surfaces of the first electrodes.

### CROSS REFERENCE TO RELATED APPLICATIONS

The present application is a US National Stage of International Application No. PCT/CN2024/093221, filed on May 14, 2024, which claims the priority from Chinese Patent Application No. 202310787059.9, filed with the China National Intellectual Property Administration on Jun. 29, 2023 and entitled “Wiring Substrate and Preparation Method therefor, and Display Apparatus”, which is hereby incorporated by reference in its entirety.

### TECHNICAL FIELD

The disclosure relates to the field of display technology, in particular to a wiring substrate, a preparation method therefor, and a display apparatus.

### BACKGROUND

Micro light-emitting diodes (micro-LEDs), due to their smaller size and advantages such as ultra-high brightness and long lifespan, are increasingly being adopted in the display field.

### SUMMARY

Some Embodiments of the disclosure provide a wiring substrate, the preparation method, and a display apparatus, to prevent the electrodes in the fan-out region from corrosion.

The wiring substrate according to embodiments of the disclosure includes: a base substrate including a fan-out region, a plurality of first electrodes on a side of the base substrate, and a first protection layer on a side of the plurality of first electrodes facing away from the base substrate. The first protection layer includes a plurality of first openings running through the first protection layer along a thickness direction of the first protection layer. Each of the plurality of first opening corresponds to one first electrode, and an orthographic projection of the first opening on the base substrate overlaps with an orthographic projection of the first electrode on the base substrate. The first protection layer at least covers side surfaces of the first electrodes.

In some embodiments, the orthographic projection of the first opening on the base substrate is located within the orthographic projection of the first electrode on the base substrate.

In some embodiments, the wiring substrate further includes: a plurality of anti-oxidation layers on the side of the plurality of first electrodes facing away from the base substrate. Each of the plurality of anti-oxidation layers is electrically connected to one of the plurality of first electrodes, and an orthographic projection of the anti-oxidation layer on the base substrate covers the orthographic projection of the first opening on the base substrate.

In some embodiments, the orthographic projection of the first opening on the base substrate is located within the orthographic projection of the anti-oxidation layer on the base substrate. The orthographic projection of the anti-oxidation layer on the base substrate covers an orthographic projection of an edge of the first protection layer at the first opening on the base substrate.

In some embodiments, the wiring substrate further includes a second protection layer on a side of the first protection layer facing away from the base substrate. The second protection layer includes a second opening. The orthographic projection of the first electrode on the base substrate is located within an orthographic projection of the second opening on the base substrate.

In some embodiments, the orthographic projection of the anti-oxidation layer on the base substrate is located within the orthographic projection of the second opening on the base substrate.

In some embodiments, the wiring substrate includes a second protection layer on a side of the first protection layer facing away from a first conductive layer. The second protection layer includes a plurality of second openings running through the second protection layer along a thickness direction of the second protection layer. An orthographic projection of the second opening on the base substrate is located within the orthographic projection of the first electrode on the base substrate.

In some embodiments, the second opening and the first opening are formed in a same patterning process.

In some embodiments, at the first opening and the second opening, the anti-oxidation layer cover a side surface of the first protection layer and a side surface of the second protection layer.

In some embodiments, at a contact position between the anti-oxidation layer and the second protection layer, a surface of the anti-oxidation layer facing away from the base substrate and a surface of the second protection layer facing away from the base substrate are in a same plane.

In some embodiments, the first electrode includes a first surface facing away from the base substrate, and a distance between an edge of the first opening and an edge of the first surface of the first electrode is greater than or equal to 8 microns and less than or equal to 9 microns.

In some embodiments, the wiring substrate further includes a plurality of second electrodes, a first insulating layer and a second insulating layer. The plurality of second electrodes is located within the fan-out region and between the base substrate and the plurality of first electrodes. Each of the plurality of second electrodes is electrically connected to one first electrode, and an orthographic projection of the second electrode on the base substrate overlaps with the orthographic projection of the first electrode on the base substrate. The first insulating layer is located between the base substrate and the plurality of second electrodes. The first insulating layer includes a plurality of third openings running through the first insulating layer along a thickness direction of the first insulating layer. An orthographic projection of the third opening is located within the orthographic projection of the first electrode on the base substrate, and within the orthographic projection of the second electrode on the base substrate. The second insulating layer is located on a side of the first insulating layer facing away from the base substrate. The first insulating layer includes a plurality of fourth openings running through the first insulating layer along the thickness direction of the first insulating layer. The orthographic projection of the third opening on the base substrate is located within an orthographic projection of the fourth opening on the base substrate. The orthographic projection of the first electrode and the orthographic projection of the second electrode on the base substrate are located within the orthographic projection of the fourth opening on the base substrate. The first electrode is electrically connected to the second electrode via the third opening and the fourth opening.

Embodiments of the disclosure provide a preparation method for the wiring substrate, including: providing a base substrate including a fan-out region, forming a plurality of first electrodes in the fan-out region of the base substrate, and forming a first protection layer on a side of the plurality of first electrodes facing away from the base substrate and performing a patterning process on the first protection layer to form a plurality of first openings running through the first protection layer along a thickness direction of the first protection layer. Each of the plurality of first opening corresponds to one first electrode, and an orthographic projection of the first opening on the base substrate overlaps with an orthographic projection of the first electrode on the base substrate. The first protection layer at least covers side surfaces of the first electrodes.

In some embodiments, after performing the patterning process on the first protection layer to form the plurality of first openings, the method further includes: using an electroless plating process to form an anti-oxidation layer on a side of each first electrode facing away from the base substrate. The orthographic projection of the anti-oxidation layer on the base substrate covers the orthographic projection of the first opening on the base substrate.

In some embodiments, after performing the patterning process on the first protection layer to form the plurality of first openings running through the first protection layer along the thickness direction of the first protection layer and before forming the anti-oxidation layers, the method further includes: forming a second protection layer on a side of the first protection layer facing away from the base substrate, and performing a patterning process on the second protection layer to form a plurality of second openings running through the second protection layer along a thickness direction of the second protection layer, where the orthographic projection of the first electrode on the base substrate is located within an orthographic projection of the second opening on the base substrate.

In some embodiments, before performing the patterning process on the first protection layer to form the plurality of first openings running through the first protection layer along the thickness direction of the first protection layer, the method further includes: forming a second protection layer on a side of the first protection layer facing away from the base substrate, and performing the patterning process on the first protection layer to form the plurality of first openings running through the first protection layer along the thickness direction of the first protection layer, includes performing a patterning process on the first protection layer and the second protection layer to form the plurality of first openings running through the first protection layer along the thickness direction of the first protection layer and a plurality of second openings running through the second protection layer along the thickness direction of the second protection layer.

In some embodiments, before forming the plurality of first electrodes in the fan-out region of the base substrate, the method further includes: forming a plurality of second electrodes in the fan-out region of the base substrate; forming a pattern of a first insulating layer on a side of the plurality of second electrodes facing away from the base substrate, the first insulating layer including a plurality of third openings running through the first insulating layer along a thickness direction of the first insulating layer, and an orthographic projection of the third opening on the base substrate being located within the orthographic projection of the first electrode on the base substrate and within an orthographic projection of the second electrode on the base substrate; forming a second insulating layer on a side of the first insulating layer facing away from the base substrate. The orthographic projection of the third opening on the base substrate is located within an orthographic projection of the fourth opening on the base substrate, and the orthographic projection of the first electrode and the orthographic projection of the second electrode on the base substrate both are located within the orthographic projection of the fourth opening on the base substrate.

Embodiments of the disclosure provide a light-emitting substrate, including the wiring substrate according to the embodiments of the disclosure, and light-emitting devices bonded to the wiring substrate.

In some embodiments, the light-emitting devices are micro-sized inorganic electroluminescent devices.

Embodiments of the disclosure provide a display apparatus, including the light-emitting substrate according to embodiments of the disclosure.

### BRIEF DESCRIPTION OF FIGURES

To better illustrate the technical solutions in the embodiments of the disclosure, a brief description of the drawings used in the embodiments is provided below. It is evident that the drawings described below illustrate only some embodiments of this disclosure. For those skilled in the art, additional drawings can be derived based on these drawings without creative effort.

FIG. 1 shows a structural schematic diagram of a wiring substrate in the related art.

FIG. 2 shows a structural schematic diagram of a wiring substrate according to embodiments of the disclosure.

FIG. 3 shows another structural schematic diagram of a wiring substrate according to embodiments of the disclosure.

FIG. 4 shows yet another structural schematic diagram of a wiring substrate according to embodiments of the disclosure.

FIG. 5 shows an enlarged view of a region D in FIG. 4 according to embodiments of the disclosure.

FIG. 6 shows an enlarged view of a region E in FIG. 4 according to embodiments of the disclosure.

FIG. 7 shows yet another structural schematic diagram of a wiring substrate according to embodiments of the disclosure.

FIG. 8 shows yet another structural schematic diagram of a wiring substrate according to embodiments of the disclosure.

FIG. 9 shows yet another structural schematic diagram of a wiring substrate according to embodiments of the disclosure.

FIG. 10 shows yet another structural schematic diagram of a wiring substrate according to embodiments of the disclosure.

FIG. 11 shows yet another structural schematic diagram of a wiring substrate according to embodiments of the disclosure.

FIG. 12 shows yet another structural schematic diagram of a wiring substrate according to embodiments of the disclosure.

FIG. 13 shows a sectional view along line GG′ in FIG. 5 according to embodiments of the disclosure.

FIG. 14 shows another sectional view along line GG′ in FIG. 5 according to embodiments of the disclosure.

FIG. 15 shows a sectional view along line JJ′ in FIG. 5 according to embodiments of the disclosure.

FIG. 16 shows another sectional view along line JJ′ in FIG. 5 according to embodiments of the disclosure.

FIG. 17 shows a flow chart of a preparation method for a wiring substrate according to embodiments of the disclosure.

FIG. 18 shows a structural schematic diagram of a light-emitting substrate according to embodiments of the disclosure.

FIG. 19 shows a structural schematic diagram of a display apparatus according to embodiments of the disclosure.

### DETAILED DESCRIPTION

In order to make objectives, technical solutions and advantages of the embodiments of the disclosure clearer, the technical solutions of the embodiments of the disclosure are described clearly and completely below with reference to the drawings of the embodiments of the disclosure. Apparently, the described embodiments are some, not all, of the embodiments of the disclosure. The embodiments in the disclosure and the features in the embodiments may be combined with each other without conflict. Based on the described embodiments of the disclosure, all other embodiments obtained by those of ordinary skill in the art without inventive efforts fall within the protection scope of the disclosure.

Unless otherwise indicated, the technical or scientific terms used in the disclosure shall have the usual meanings understood by a person of ordinary skill in the art to which the disclosure belongs. The words “first”, “second” and the like used in the disclosure do not indicate any order, quantity or importance, but are only used to distinguish different components. The word “including” or “containing” and the like, means that an element or item preceding the word covers an element or item listed after the word and the equivalent thereof, without excluding other elements or items. The word “connection” or “coupling” and the like is not restricted to physical or mechanical connection, but may include electrical connection, whether direct or indirect.

It should be noted that sizes and shapes of all figures in the drawings do not reflect a true scale and are only intended to illustrate the contents of the disclosure. Same or similar reference signs indicate same or similar elements or elements with the same or similar function throughout the disclosure.

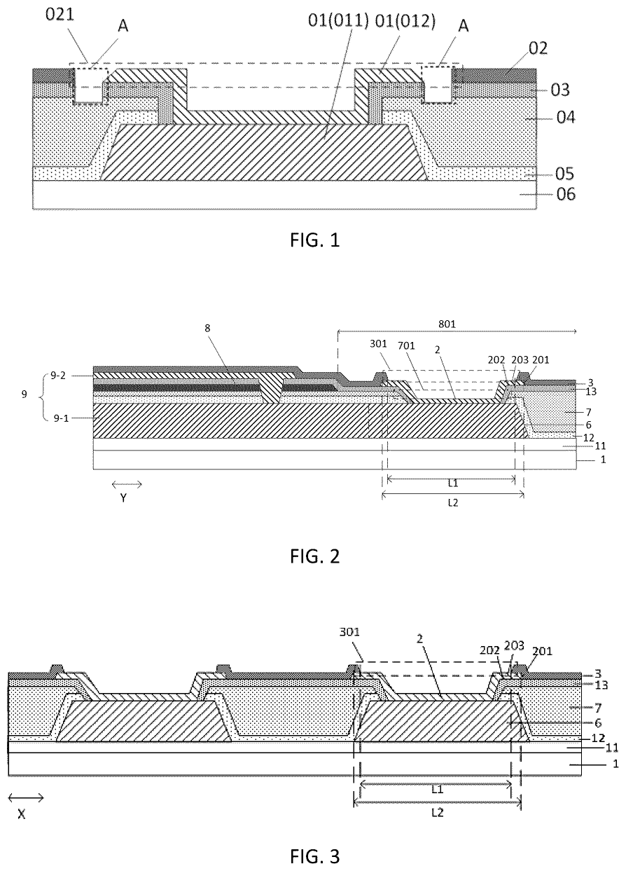

In the related art, as shown in FIG. 1, a wiring substrate includes: an electrode structure 01 bonded to a circuit board on a side of the substrate 06, and a protection layer 02 covering the electrode structure 01. The electrode structure 01 includes a lower electrode 011 and an upper electrode 012 connected to the lower electrode 011. The protection layer 02 has a large opening to expose a surface of the upper electrode 012. The wiring substrate also includes a first insulating film layer 03, a second insulating film layer 04, and a third insulating film layer 05 between the upper electrode 012 and the lower electrode 011. To ensure the electrical connection between the circuit board and the electrode structure 01, the opening of the protection layer 02 usually completely exposes the surface of the upper electrode 012, meaning the protection layer 02 does not cover the upper electrode 012. The upper electrode 012 typically has a stacked structure, for example, including a copper layer directly in contact with the lower electrode 011 and a molybdenum-niobium alloy layer on a side of the copper layer facing away from the lower electrode 011. Furthermore, the wiring substrate includes multiple pads in the same layer as the upper electrode 012. The pads also include a copper layer and a molybdenum-niobium alloy layer, and the surfaces of the pads need to be exposed by the opening of the protection layer 02 to allow the pads to connect to the pins of other components via solder. Thus, the surfaces of the pads exposed by the opening of the protection layer 02 should be available for soldering. Since the molybdenum-niobium alloy layer only provides anti-oxidation functionality and has poor availability for soldering, the molybdenum-niobium alloy layer must be removed before soldering to ensure reliable connections between the pads and the components via solder. Thus, during the manufacturing process of the wiring substrate, during the process of forming the openings in the protection layer 02, it some cases, it is necessary to perform an over-etching process on the protection layer 02 to ensure the reliability of other areas of the wiring substrate. In this process, not only is the molybdenum-niobium alloy layer removed in the exposed area of the upper electrode 012, but also part of the first insulating film layer 03 and the second insulating film layer 04 under the protection layer 02 is etched away. In the region A shown in FIG. 1, the protection layer 02 is completely removed, and part of the first insulating film layer 03 and the second insulating film layer 04 is etched away. Due to the lack of protection from the protection layer 02 in this region, moisture can easily infiltrate along the interface between the upper electrode 012 and the first insulating film layer 03, and further can easily infiltrate along the second insulating film layer 04, causing corrosion of the lower electrode 011.

Embodiments of the disclosure provide a wiring substrate, as shown in FIGS. 2 and 3. The wiring substrate includes: a base substrate 1 including a fan-out region 101, a plurality of first electrodes 2 on a side of the base substrate 1, and a first protection layer on a side of the plurality of first electrodes 2 facing away from the base substrate 1.

The first protection layer 3 includes a plurality of first openings 301 running through the first protection layer along a thickness direction of the first protection layer. Each first opening 301 corresponds to one first electrode 2. An orthographic projection of the first opening 301 on the base substrate 1 overlaps with an orthographic projection of the first electrode 2 on the base substrate 1. The first protection layer 3 at least covers a side surface 201 of the first electrode 2.

In the wiring substrate according to embodiments of the disclosure, the first protection layer at least covers the side surface of the first electrode, meaning the first opening does not expose an entire region of the first electrode. By setting the first opening with a relatively small size, the first protection layer can protect the side surface of the first electrode, moisture infiltration from the side surface of the first electrode can be prevented, thereby avoiding corrosion and ensuring the yield of the wiring substrate.

It should be noted that, as shown in FIGS. 2 and 3, the first electrode 2 further includes a second surface 202 facing to the base substrate 1 and a first surface 203 facing away from the base substrate 1. The side surface 201 of the first electrode 2 connects the second surface 202 and the first surface 203.

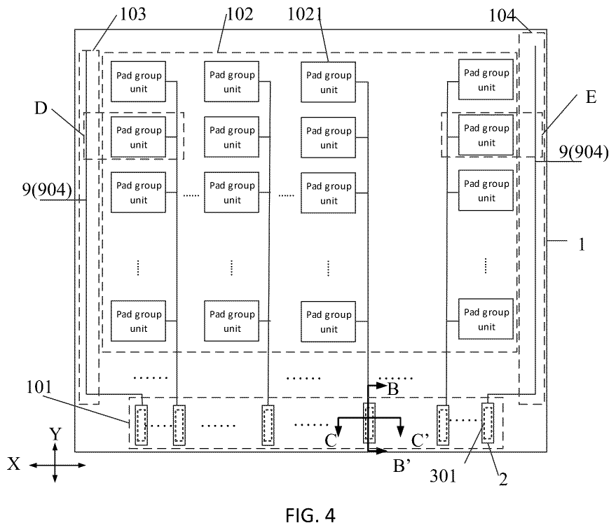

In some embodiments, as shown in FIG. 4, in the fan-out region 10, the plurality of first electrodes 2 are arranged along a first direction X. The number of first openings 301 equals the number of first electrodes 2, with one first opening 301 corresponding to one first electrode 2. That is, the plurality of first openings 301 are also arranged along the first direction X.

It should be noted that FIG. 2, for example, shows a cross-sectional view along line BB′ in FIG. 4, and FIG. 3 shows a cross-sectional view along line CC′ in FIG. 4.

In specific implementations, the plurality of first electrodes are used for bonding with a circuit board, serving as signal input terminals of the wiring substrate. The circuit board may be a flexible circuit board or a printed circuit board.

In some embodiments, as shown in FIG. 4, the base substrate 1 further includes: a pad region 102, and a first peripheral region 103 and a second peripheral region 104 located on two side of the pad region 102 along the first direction X. In the second direction Y, the fan-out region 10 is located on one side of the pad region 102. The second direction Y intersects the first direction X. In this example, the second direction Y is perpendicular to the first direction X in FIG. 4. The pad region 102 includes a plurality of pad group units 1021.

In some embodiments, as shown in FIG. 4, the wiring substrate further includes a plurality of signal lines 9, which are electrically connected to the pad group units 1021 and the first electrodes 2.

In specific implementations, the wiring substrate according to embodiments of the disclosure can be applied to a light-emitting substrate. The first pad group is used for bonding with a light-emitting device, and the second pad group is used for bonding with a driver chip. In this way, signals provided by the circuit board can be transmitted to the corresponding signal lines via the first electrodes and then to the pad group units to drive the light-emitting devices to emit light.

In some embodiments, as shown in FIGS. 2 to 4, the orthographic projection of the first opening 301 on the base substrate 1 is located within the orthographic projection of the first electrode 2 on the base substrate 1. That is, as shown in FIGS. 2 and 3, the first protection layer 3 not only covers the side surface of the first electrode 2 but also partially covers the surface of the first electrode 2 facing away from the base substrate 1. This can avoid exposure of the side surface of the first electrode due to process errors, enhance the protective effect of the first protection layer on the side surface of the first electrode, and prevent corrosion caused by moisture infiltration from the side surface, thereby improving the yield of the wiring substrate.

In some embodiments, as shown in FIGS. 2 and 3, in any direction parallel to the plane of the base substrate 1, a first width L1 of the first opening 301 is smaller than a width L2 of the first surface 203 of the first electrode 2.

It should be noted that in FIGS. 2 and 3, at the first opening 301, a side surface of the first protection layer 3 is an inclined surface that is not perpendicular to the plane of the base substrate 1. The first width L1 of the first opening 301 refers to a minimum width of the first opening 301 in a direction parallel to the plane of the base substrate.

In some embodiments, L2-L1 is a distance between an edge of the first opening and an edge of the first surface, and L2-L1 is greater than or equal to 8 μm and less than or equal to 9 μm.

In some embodiments, in the first direction X, L1 is greater than or equal to 190 μm and less than or equal to 194 μm, L2 is greater than or equal to 198 μm and less than or equal to 202 μm. In the second direction Y, L1 is greater than or equal to 790 μm and less than or equal to 794 μm, while L2 is greater than or equal to 798 μm and less than or equal to 802 μm.

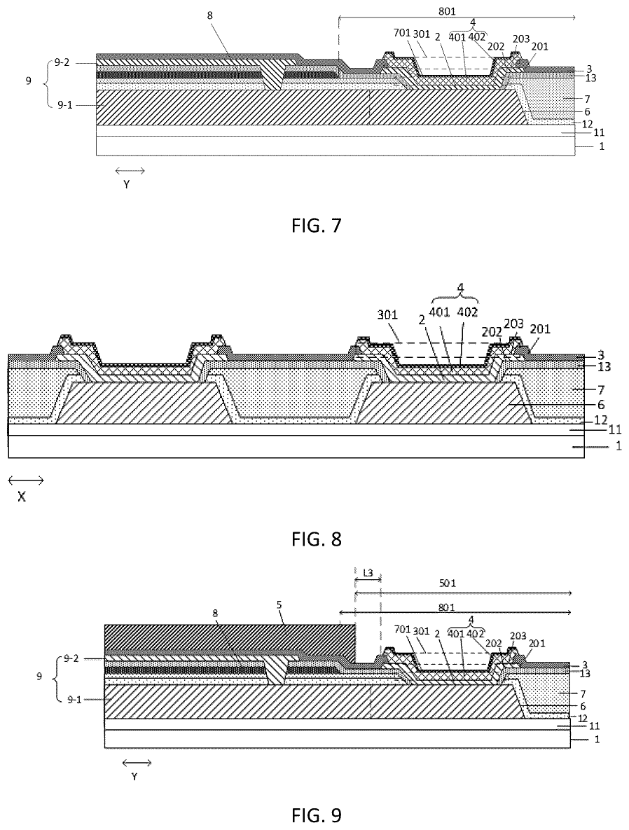

In some embodiments, as shown in FIGS. 7 and 8, the wiring substrate further includes: a plurality of anti-oxidation layers 4 on the side of the plurality of first electrodes 2 facing away from the base substrate 1. Each anti-oxidation layer 4 is electrically connected to one of the plurality of first electrodes 2. An orthographic projection of the anti-oxidation layer 4 on the base substrate 1 cover an orthographic projection of the first openings 301 on the base substrate 1.

It should be noted that FIG. 7 shows a cross-sectional view along line BB′ in FIG. 4, and FIG. 8 shows a cross-sectional view along line CC′ in FIG. 4.

The wiring substrate according to embodiments of the disclosure includes the anti-oxidation layer on the side of the first electrode facing away from the base substrate, which can protect the surface of the first electrode facing away from the base substrate and improve the electrical bonding performance between the wiring substrate and the circuit board.

In specific implementations, the anti-oxidation layer on the side of the first electrode facing away from the substrate is bonded to the circuit board. For example, the anti-oxidation layer and the circuit board can be electrically connected via conductive adhesive to realize bonding between them. The conductive adhesive can be, for example, anisotropic conductive adhesive.

In some embodiments, as shown in FIGS. 7 and 8, the orthographic projection of the first opening 301 on the base substrate 1 is located within the orthographic projection of the anti-oxidation layer 4 on the base substrate 1. Furthermore, the orthographic projection of the anti-oxidation layer 4 on the base substrate 1 covers the orthographic projection of the edge of the first protection layer 3 at the first opening 301 on the base substrate 1.

In some embodiments, as shown in FIGS. 7 and 8, the anti-oxidation layer 4 includes a first sub-layer 401 and a second sub-layer 402 that are stacked on the side of the first electrode 2 facing away from the base substrate 1.

In specific implementations, the anti-oxidation layer is formed using an electroless plating process, where the first sub-layer is grown first, followed by the second sub-layer.

In some embodiments, a material of the first electrode includes copper, a material of the first sub-layer of the anti-oxidation layer includes nickel, and a material of the second sub-layer of the anti-oxidation layer includes gold.

In specific implementations, the anti-oxidation layer is formed via an Electroless Nickel Immersion Gold (ENIG) process, where the nickel layer is grown first as the first sub-layer, followed by the gold layer as the second sub-layer.

In some embodiments, a thickness of the first sub-layer is greater than a thickness of the second sub-layer. The thickness of the first sub-layer is greater than a thickness of the first opening.

In some embodiments, the thickness of the first sub-layer is greater than or equal to 4 μm and less than or equal to 5 μm, while the thickness of the second sub-layer is greater than or equal to 0.01 μm and less than or equal to 1 μm. In this case, the thickness of the nickel layer is greater than or equal to 4 μm and less than or equal to 5 μm, and the thickness of the gold layer is greater than or equal to 0.01 μm and less than or equal to 1 μm.

In specific implementations, the total thickness of the anti-oxidation layer is greater than or equal to 4.01 μm and less than or equal to 6 μm. For example, the total thickness of the anti-oxidation layer is 5 μm.

In specific implementations, when the anti-oxidation layer is formed using the ENIG process, the nickel layer and the gold layer are formed sequentially based on replacement reaction, the size of the anti-oxidation layer is constrained by the size of the corresponding first electrode. The orthographic projection of the anti-oxidation layer on the base substrate can overlap with or be located within the orthographic projection of the first electrode on the base substrate. In any direction parallel to the plane of the base substrate, the width of the anti-oxidation layer is less than or equal to the width of the corresponding first electrode.

On this basis, when the first protection layer covers the edge of the first electrode, the orthographic projection of the anti-oxidation layer on the base substrate covers the orthographic projection of the edge of the first protection layer at the first opening on the base substrate. Further, in any direction parallel to the plane of the base substrate, the width of the anti-oxidation layer is equal to the width of the corresponding first electrode. This configuration maximizes the size of the anti-oxidation layer under process constraints, thereby maximizing the bonding area between the anti-oxidation layer and the circuit board and improving bonding yield.

It should be noted that FIGS. 7 and 8 illustrate an example where only a first protection layer 3 is provided on the side of the first electrode 2 facing away from the base substrate 1. In some embodiments, as shown in FIGS. 9 to 11, the wiring substrate further includes: a second protection layer 5 on a side of the first protection layer 3 facing away from the base substrate 1, including a second opening 501.

It should be noted that the first protection layer is relatively thin, typically around 2400 Å. Since the structures covered by the first protection layer are not flat, cracks may occur in the thin first protection layer over uneven areas, reducing its protective effectiveness. In embodiments of the disclosure, the wiring substrate further includes a second protection layer on the side of the first protection layer facing away from the base substrate. Even if cracks occur in the first protection layer, the second protection layer can cover the cracks to prevent moisture infiltration, thereby enhancing protection and improving the yield of the wiring substrate.

It should be noted that the thickness of the second protection layer is greater than the thickness of the first protection layer. The thickness of the first protection layer is approximately 2400 Å, while the thickness of the second protection layer is around 3 μm. In related art, in the case that the wiring substrate includes the second protection layer, the opening in the second protection layer must also expose the first electrode, resulting in large openings in both the first protection layer and the second protection layer. Additionally, in related art, there is no anti-oxidation layer on the side of the first electrode facing away from the base substrate, if the opening in the first protection layer is made smaller, relatively large segment differences between layers at the opening can occur. When the first electrode is bonded to the circuit board via conductive adhesive, these segment differences can affect the fill of the adhesive, resulting in low fluidity of the adhesive, so that there will be areas where the adhesive does not contact the first electrodes, thereby reducing bonding reliability. In contrast, the wiring substrate according to the embodiments of the disclosure includes the anti-oxidation layer on the side of the first electrode facing away from the base substrate. The anti-oxidation layer is thick enough to mitigate the issues caused by segment differences, even when the opening in the first protection layer is small. Thus, the impact on the bonding performance can be avoided and the bonding yield can be improved.

In some embodiments, as shown in FIG. 9, the orthographic projection of the first electrode 2 on the base substrate 1 is located within an orthographic projection of the second opening 501 on the base substrate 1.

In some embodiments, as shown in FIG. 9, the orthographic projection of the anti-oxidation layer 4 on the base substrate 1 is located within the orthographic projection of the second opening 501 on the base substrate 1.

In this case, in FIG. 9, the second opening in the second protection layer exposes the region where the first electrode and the anti-oxidation layer are located, forming a large opening.

In the wiring substrate according to the embodiments of the disclosure, the second opening in the second protection layer exposing the region of the first electrode and anti-oxidation layer is a large opening, which can reduce the segment difference in this region and improve the fluidity of the conductive adhesive, helping to increase the bonding yield.

In some embodiments, as shown in FIG. 12, the second protection layer 5 includes one second opening 501, and the second opening 501 corresponds to the plurality of first electrodes 2 and the plurality of anti-oxidation layers 4. In this case, the orthographic projection of the plurality of first electrodes 2 on the base substrate 1 is located within the orthographic projection of the second opening 501 on the base substrate, and the orthographic projection of the plurality of anti-oxidation layers 4 on the base substrate 1 is located within the orthographic projection of the second opening 501 on the base substrate 1.

It should be noted that FIG. 9 shows a cross-sectional view along the FF′ line in FIG. 12, and the cross-sectional view along the GG′ line in FIG. 12 is the same as in FIG. 8. This means that there is no second protection layer between two adjacent electrodes in the first direction X.

In some embodiments, as shown in FIG. 9, a distance L3 between the second protection layer 5 and the first electrode 2 in the region corresponding to the second opening 501 is greater than or equal to 498 microns and less than or equal to 502 microns.

In specific implementations, in the first direction, a distance between two adjacent first electrodes is greater than or equal to 58 microns and less than or equal to 62 microns, meaning the distance between adjacent first electrodes is small. When the second protection layer's opening needs to expose the first electrode, the second protection layer in the area between the two adjacent first electrodes is removed, which helps reduce the difficulty in patterning the second protection layer.

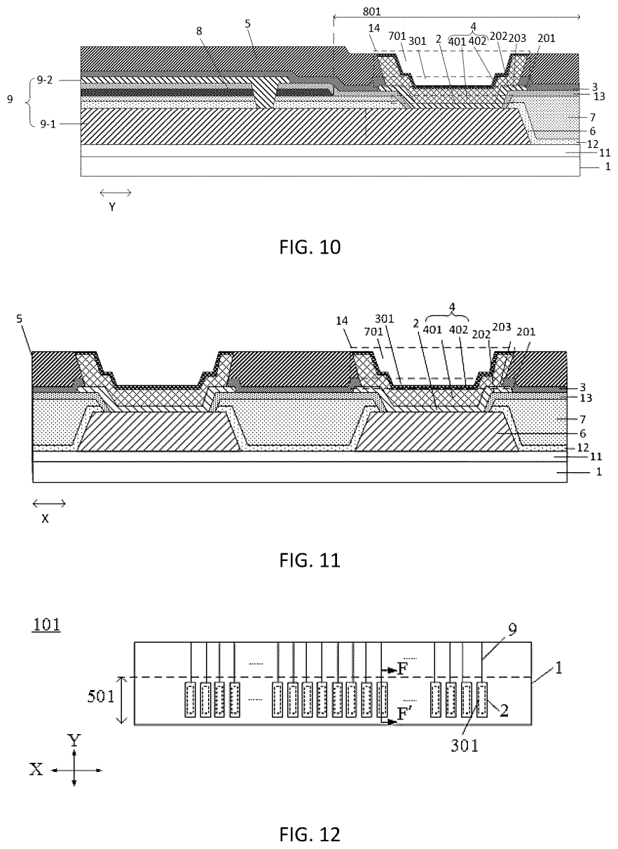

Alternatively, in some embodiments, as shown in FIGS. 10 and 11, the orthographic projection of the second opening 501 on the base substrate 1 is located within the orthographic projection of the first electrode 2 on the base substrate 1, and the second protection layer 5 covers the surface of the first protection layer 3 facing away from the base substrate 1.

In this case, in the wiring substrate according to the embodiments of the disclosure, the second opening exposing only a portion of the first electrode is a small opening. Since the first protection layer covers the side surface of the first electrode, the first protection layer needs to slope to cover the side surface of the first electrode. Since the first protection layer is thin, cracks may easily form at the edge of the first electrode. In the wiring substrate according to the embodiments of the disclosure, the second opening exposing only part of the first electrode is a small opening and the second protection layer covers the first protection layer, the protection to the first electrode can be improved. Even if cracks form in the first protection layer, the second protection layer prevents moisture from entering along the cracks, thus preventing corrosion of the first electrode.

In some embodiments, the number of second openings is equal to the number of first electrodes. In this case, one second opening corresponds to one first electrode.

In some embodiments, as shown in FIGS. 10 and 11, the second opening 501 and the first opening 301 are formed in a same patterning process. Specifically, after forming the first protection layer, the first opening is not formed immediately but rather after forming the second protection layer. Then, both the second protection layer and the first protection layer are patterned to form the opening 14, which include both the second opening 501 and the first opening 301, running through the second protection layer 5 and the first protection layer 3 along the thickness direction.

In the wiring substrate according to the embodiments of the disclosure, the second opening and the first opening are made in the same patterning process, simplifies the fabrication process and only requires one mask for the patterning process, reducing costs.

In some embodiments, as shown in FIGS. 10 and 11, at the first opening 301 and the second opening 501, the anti-oxidation layer 4 covers the side surface of the first protection layer 3 and a side surface of the second protection layer 5.

In some embodiments, as shown in FIGS. 10 and 11, at a position where the anti-oxidation layer 4 contacts the second protection layer 5, a surface of the anti-oxidation layer 4 facing away from the base substrate 1 and a surface of the second protection layer 5 facing away from the base substrate 1 are in a same plane.

In the wiring substrate according to embodiments of the disclosure, the anti-oxidation layer covers both the side surface of the first protection layer and the side surface of the second protection layer, so that the protection of the first electrode can be improved. Additionally, at the contact position between the anti-oxidation layer and the second protection layer, the surface of the anti-oxidation layer facing away from the base substrate 1 and the surface of the second protection layer facing away from the base substrate 1 are aligned in the same plane, which can reduce the segment difference in this region and improve the fluidity of the conductive adhesive, helping to increase the bonding yield.

In some embodiments, as shown in FIGS. 2, 7, 9, and 10, the wiring substrate further includes:
a plurality of second electrodes 6 in the fan-out area and between the base substrate 1 and the first electrodes 2. Each second electrode 6 is electrically connected to one first electrode 2, and an orthographic projection of the second electrode 6 on the base substrate 1 overlaps with the orthographic projection of the first electrode 2 on the base substrate 1;
a first insulating layer 7 on a side of the second electrodes 6 facing away from the base substrate; the first insulating layer 7 includes a plurality of third openings 701 running through the first insulating layer along a thickness direction of the first insulating layer 7; an orthographic projection of the third opening 701 on the base substrate 1 is located within the orthographic projection of the first electrode 2 and the orthographic projection of the second electrode 6;
a second insulating layer 8 on a side of the first insulating layer 7 facing away from the base substrate 1; the second insulating layer 8 includes a plurality of fourth openings 801; the orthographic projection of the third opening 701 on the base substrate 1 is located within an orthographic projection of the fourth opening 801 on the base substrate 1, and the orthographic projections of both the first electrode 2 and the second electrode 6 are located within the orthographic projection of the fourth opening 801; and the first electrode 2 is electrically connected to the second electrode 6 at the third opening 701 and the fourth opening 801.

The wiring substrate according to the embodiments of the disclosure further includes the second electrode electrically connected to the first electrode in the fan-out region. That is, the electrically connected first electrode and second electrode together serve as the signal input terminal of the wiring substrate. The dual-layer wiring of the signal input terminal helps increase the size of the signal input terminal, thereby reducing the impedance. Additionally, both the orthographic projection of the first electrode and the second electrode on the base substrate are located within the orthographic projection of the fourth opening on the base substrate, meaning that the orthographic projection of the first electrode on the base substrate does not overlap with the orthographic projection of the second insulating layer on the base substrate. This ensures that there is no second insulating layer directly beneath the first electrode, thus reducing the number of layers at the connection between the first and second electrodes. This reduces the layer thickness and avoids large segment differences at the connection area, improving the yield of the wiring substrate.

In specific implementations, as shown in FIGS. 2, 7, 9, and 10, the wiring substrate further includes: a buffer layer 11 between the second electrode 6 and the base substrate 1, a third insulating layer 12 between the second electrode 6 and the first insulating layer 7, and a fourth insulating layer 13 between the first insulating layer 7 and the second insulating layer 8. Both the third insulating layer 12 and the fourth insulating layer 13 have openings, and orthographic projections of the openings in the third insulating layer 12 and the fourth insulating layer 13 on the base substrate 1 are located within the orthographic projection of the first electrode 2 on the base substrate 1. That is, the first electrode 2 is electrically connected to the second electrode 6 through openings that pass through the fourth insulating layer 13, the first insulating layer 7, and the third insulating layer 12.

In specific implementations, the buffer layer prevents the second electrode from being directly attached to the substrate and falling off. The first insulating layer and the second insulating layer also function as planarization layers.

In a particular example, a thickness of the first insulating layer is approximately 3.5 microns, a thickness of the second insulating layer is approximately 4 microns, a thickness of the third insulating layer is approximately 2400 angstroms, and a thickness of the fourth insulating layer is approximately 1200 angstroms.

During implementations, the first protection layer, the third insulating layer, and the fourth insulating layer are inorganic, meaning the first protection layer, the third insulating layer, and the fourth insulating layer include inorganic insulating materials such as, at least one of silicon nitride, silicon oxide, silicon oxynitride, or amorphous silicon. The second protection layer, the first insulating layer, and the second insulating layer are organic, meaning the second protection layer, the first insulating layer, and the second insulating layer include organic insulating materials such as dipentaerythritol pentaacrylate, dipentaerythritol hexacrylate mixture, acrylic acid and acrylic ester copolymers, and photoinitiators.

In some embodiments, as shown in FIGS. 2, 7, 9, and 10, at least in the fan-out region, the signal line 9 includes a first sub-signal line 9-1 and a second sub-signal line 9-2 in different layers. That is, the signal line 9 is dual-layered in the fan-out region, which helps increase the resistance of the signal line, reducing its impedance and preventing excessive signal loss due to high impedance.

During implementations, in a region outside the fan-out region, the signal line may include at least one of the first sub-signal line or the second sub-signal line.

In some embodiments, as shown in FIGS. 2, 7, 9, and 10, the first sub-signal line 9-1 is in the same layer as the second electrode 6, while the second sub-signal line 9-2 is in the same layer as the first electrode 2. The second sub-signal line 9-2 is electrically connected to the first sub-signal line 9-1 through a via passing through the fourth insulating layer 13, the second insulating layer 8, the first insulating layer 7, and the third insulating layer 12.

The layer where the second sub-signal line and the first electrode are located is referred to as a first conductive layer, while the layer where the first sub-signal line and the second electrode are located is referred to as the second conductive layer.

In some embodiments, as shown in FIGS. 2, 7, 9, and 10, the first sub-signal line 9-1 is connected to the second electrode 6. This enables the signal line to be electrically connected to both the second electrode and the first electrode, and further connected to the circuit board.

In specific implementations, for example, the first sub-signal line 9-1 is formed integrally with the second electrode 6.

In specific implementations, as shown in FIGS. 2, 7, 9, and 10, the second sub-signal line 9-2 is disconnected from the first electrode 2.

In specific implementations, the second sub-signal line may be connected to the first electrode, while the first sub-signal line is disconnected from the second electrode.

In specific implementations, the first conductive layer and the second conductive layer may include a third sub-layer made of copper. Additionally, the first conductive layer and the second conductive layer may further include a fourth sub-layer on the side of the third sub-layer facing away from the base substrate. Specifically, the third sub-layer is made of copper, and the fourth sub-layer is a molybdenum-niobium layer formed by magnetron sputtering on the surface of the copper layer facing away from the base substrate. The molybdenum-niobium layer protects the copper from corrosion, increases the surface adhesion of the first conductive layer and the second conductive layer, and helps prevent layer lift-off. It should be noted that the first electrode exposed by the first opening does not include the fourth sub-layer, i.e., the molybdenum-niobium layer, as the first opening is formed through an over-etching process, and the molybdenum-niobium layer on the surface of the first electrode in that area is removed in the patterning process for the first opening.

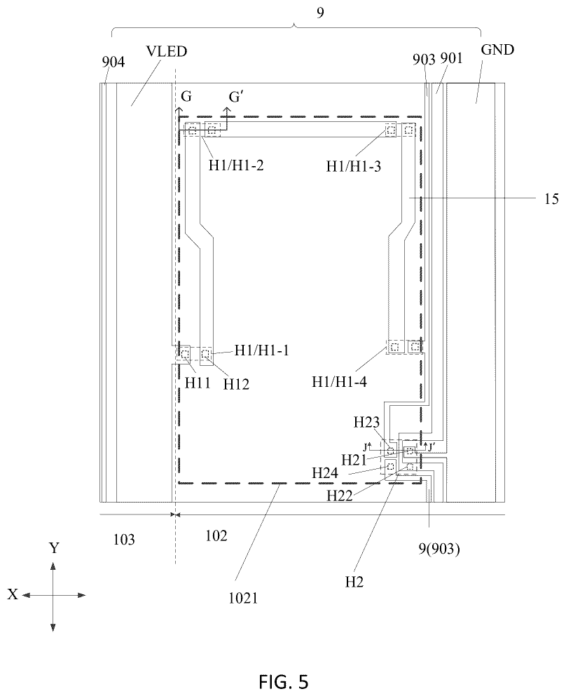

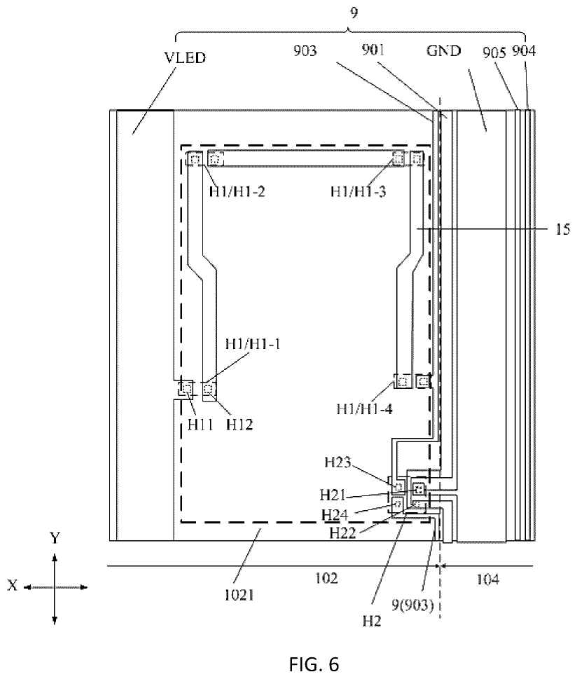

In some embodiments, as shown in FIGS. 5 and 6, each pad group unit 1021 includes: at least one first pad group H1 and a second pad group H2 electrically connected to the at least one first pad group H1. The first pad group H1 includes the first pad H11 and the second pad H12, while the second pad group H2 includes: a ground pad H21, an output pad H23, an address pad H24, and a power pad H22.

It should be noted that FIG. 5 shows a structural schematic diagram of the region D in FIG. 4, and FIG. 6 shows a structural schematic diagram of the region E in FIG. 4.

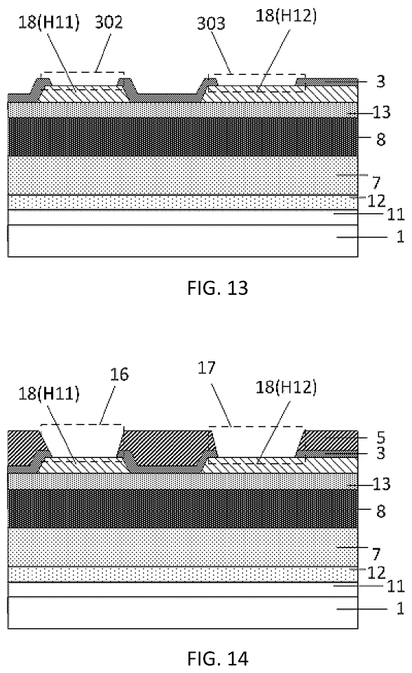

In some embodiments, as shown in FIGS. 13 and 14 which show the cross-sectional view of GG′ in FIG. 5, the first pad H11 and the second pad H12 are located within the same layer as the first electrode. Both the first pad H11 and the second pad H12 are located within the first conductive layer 18.

In specific implementations, if the first protection layer but not the second protection layer is provided on the surface of the first electrode facing away from the substrate, as shown in FIG. 13, the wiring substrate further includes a plurality of fourth openings 302 and a plurality of fifth openings 303 that pass through the first protection layer 3 and expose the first conductive layer 18. An orthographic projection of the fourth opening 302 and an orthographic projection of the fifth opening 303 on the base substrate 1 are located within an orthographic projection of the first conductive layer 18 on the base substrate. The fourth opening 302 exposes part of the first conductive layer 18, which forms the first pad H11, and the fifth opening 303 exposes part of the first conductive layer 18, which forms the second pad H12.

In specific implementations, if the first protection layer and the second protection layer are provided on the side of the first electrode facing away from the base substrate, as shown in FIG. 14, the wiring substrate further includes a plurality of sixth openings 16 and a plurality of seventh openings 17 that pass through the first protection layer 3 and the second protection layer 4 and expose the first conductive layer 18. An orthographic projection of the sixth opening 16 and an orthographic projection of the seventh opening 17 on the base substrate 1 are located within the orthogonal projection of the first conductive layer 18 on the base substrate 1. The part of the first conductive layer 18 exposed by the sixth opening 16 is the first pad H11, and the part of the first conductive layer 18 exposed by the seventh opening 17 is the second pad H12.

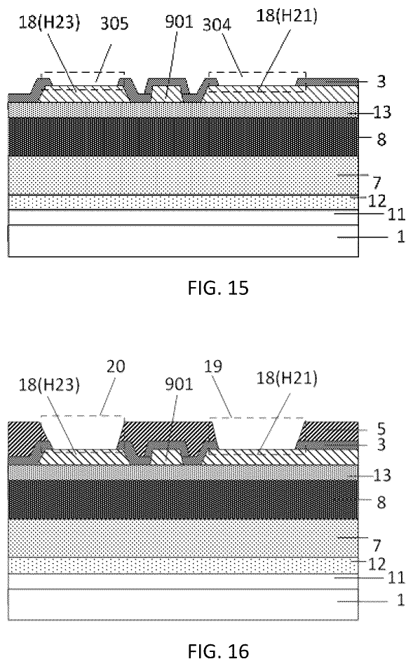

In some embodiments, as shown in FIGS. 15 and 16 which show cross-sectional view along line JJ′ in FIG. 5, the ground pad H21, the output pad H23, the address pad (not shown), and the power pad (not shown) in the second pad group H2 are in the same layer as the first electrode. The ground pad H21, the output pad H23, the address pad (not shown), and the power pad (not shown) in the second pad group H2 are all located within the first conductive layer 18.

It should be noted that in FIG. 5, the second pad group includes four pads, and the second pad group includes one output pad as an example. Of course, the second pad group can include multiple output pads.

In specific implementations, if the first protection layer, but not a second protection layer, is provided on one side of the first electrode facing away from the base substrate, as shown in FIG. 15, the wiring substrate further includes a plurality of eighth openings 304, a plurality of ninth openings 305, a plurality of tenth openings (not shown), and a plurality of eleventh openings (not shown) that pass through the first protection layer 3 and expose the first conductive layer 18. An orthographic projection of the eighth opening 304, an orthographic projection of the ninth opening 305, an orthographic projection of the tenth opening (not shown), and an orthographic projection of eleventh opening (not shown) on the base substrate 1 all are located within the orthographic projection of the first conductive layer 18 on the base substrate 1. The part of the first conductive layer 18 exposed by the eighth opening 304 is the ground pad H21, the part of the first conductive layer 18 exposed by the ninth opening 305 is the output pad H23, the part of the first conductive layer 18 exposed by the tenth opening is the address pad, and the part of the first conductive layer 18 exposed by the eleventh opening is the power pad.

In specific implementations, if both the first protection layer and the second protection layer are provided on one side of the first electrode facing away from the base substrate, as shown in FIG. 16, the wiring substrate further includes a plurality of twelfth openings 19, a plurality of thirteenth openings 20, a plurality of fourteenth openings (not shown), and a plurality of fifteenth openings (not shown) that pass through both the first protection layer 3 and the second protection layer 4 and expose the first conductive layer 18. An orthographic projection of the twelfth opening 19, an orthographic projection of the thirteenth opening 20, an orthographic projection of the fourteenth opening, and an orthographic projection of the fifteenth opening on the base substrate 1 are all located within the orthographic projection of the first conductive layer 18 on the base substrate 1. The part of the first conductive layer 18 exposed by the twelfth opening 19 is the ground pad H21, the part the first conductive layer 18 exposed by the thirteenth opening 20 is the output pad H23, the part the first conductive layer 18 exposed by the fourteenth opening is the address pad, and the part the first conductive layer 18 exposed by the fifteenth opening is the power pad.

In specific implementations, as shown in FIGS. 5 and 6, the plurality of signal lines 9, for example, include: a plurality of constant voltage signal lines VLED, a plurality of common voltage signal lines GND, a plurality of power supply signal lines 901, a plurality of address signal lines (not shown), and a plurality of cascade lines 903. In specific implementations, the address signal lines 902, the cascade lines 903, and the power supply signal lines 901 all include portions in the pad region 102.

In specific implementations, the address signal lines include a first address signal line and a second address signal line.

It should be noted that in FIGS. 5 and 6, the pad group unit 1021 includes four first pad groups H1 connected in series as an example. Each first pad group H1 is regarded as a whole, and the four first pad groups H1 are connected in series, with the four first pad groups H1 being indicated as H1-1, H1-2, H1-3, and H1-4. The constant voltage signal line VLED is electrically connected to the first pad H11 of the first pad group H1-1. Of course, each pad group unit may include other numbers of first pad groups. When each pad group unit includes multiple first pad groups, the first pad groups can be connected in series or parallel.

In specific implementations, the plurality of second pad groups in a column of pad group units can be connected in series. The address pad of a first level second pad group in the column is connected to the first address signal line. As shown in FIGS. 5 and 6, the output pad H23 of a kth (k being a positive integer) level second pad group H2 and the address pad H24 of a (k+1)th level second pad group H2 are connected via the cascade line 903, and the output pad H23 of a last level second pad group H2 is connected to the feedback signal line 905. The second address signal line (not shown) is located between the common voltage signal line GND between two adjacent pad group columns, and the constant voltage signal line VLED, and the second address signal line 9022 is electrically connected to the first address signal line 9021 on the side of the pad region far from the fan-out area. The cascade line 903 is also electrically connected to the second pad H22 of the first pad group H1 (the second pad H22 in H1-4 in FIGS. 2 and 3). Each power pad H22 in the pad group column 5-1 is electrically connected to the same power supply signal line 901; and each ground pad H21 in the pad group column 5-1 is electrically connected to the same common voltage signal line GND.

In specific implementations, as shown in FIGS. 5 and 6, for various signal lines 9 electrically connected to the pad group unit 1021, the cascade lines 903 and the power supply signal lines 901 are located between the first pad group H1 and the common voltage signal line GND, the cascade line 903 is located within the area between the power supply signal line 901 and the first pad group H1. The address signal line 902 is located at a side of the power supply signal line 901 facing away from the common voltage signal line GND adjacent to the power supply signal line.

In some embodiments, as shown in FIGS. 5 and 6, electrostatic shielding lines 904 pass through the first peripheral area 103 and the second peripheral area 104. The first peripheral area 103 includes electrostatic shielding lines 904, power supply signal lines 901, feedback signal lines 905, and fixed voltage signal lines GND, while the second peripheral area 104 includes electrostatic shielding lines 904 and constant voltage signal lines VLED.

In some embodiments, as shown in FIGS. 5 and 6, the power supply signal line 901 is integrally connected to the power pad H22. The power supply signal line 901 passes through the area between the ground pad H21 and the output pad H23, connecting to the power pad H22, with the ground pad H21 electrically connected to the common voltage signal line GND.

In specific implementations, as shown in FIGS. 5 and 6, the pad group unit 1021 further includes three first connection lines 15: two longitudinal first connection lines 15 extending along the first direction Y, and one lateral first connection line 15 extending along the second direction X. The first pad group H1-1 is electrically connected to the first pad group H1-2 via the longitudinal first connection line 15, the first pad group H1-3 is electrically connected to the first pad group H1-4 via the longitudinal first connection line 15, and the first pad group H1-2 is electrically connected to the first pad group H1-3 via the lateral first connection line 15.

In specific implementations, if the signal lines are single-layered in regions outside the fan-out region, to reduce process steps and save production costs, the constant voltage signal lines, cascade lines, address signal lines, feedback signal lines, power signal lines, first connection lines, and common voltage signal lines can be arranged in the same layer, meaning that the above structures are located within the same conductive layer. For example, in a single-layered wiring region, the above structures are arranged in the same layer as the first electrode. It should be noted that in the disclosure, “same-layer arrangement” refers to forming the film layer for creating specific patterns using the same one film-forming process and then using the same mask to form the layer structure through a single patterning process. That is, one patterning process corresponds to one mask. Depending on the specific pattern, the patterning process may include exposure, development, or etching, and the specific pattern formed in the layer structure can be continuous or discontinuous. These specific patterns can be at the same height or thickness, or they may be at different heights or thicknesses.

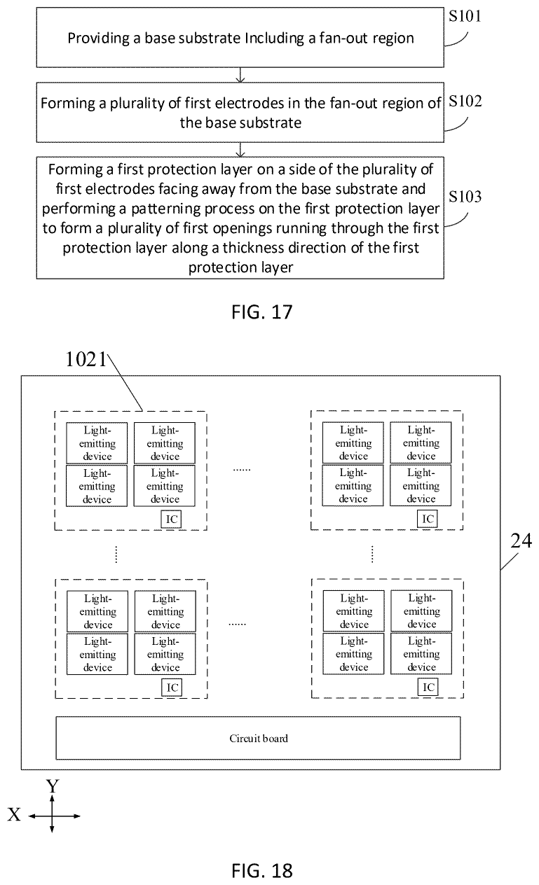

Based on the same inventive concept, embodiments of the disclosure further provide a method for preparing a wiring substrate, as shown in FIG. 17, including:
S101: providing a base substrate, where the base substrate includes a fan-out region;
S102: forming a plurality of first electrodes in the fan-out region of the base substrate;
S103: forming a first protection layer on a side of the plurality of first electrodes facing away from the base substrate, and performing a patterning process on the first protection layer to form a plurality of first openings that pass through the first protection layer along a thickness direction of the first protection layer; each of the plurality of first openings corresponds to one first electrode, and an orthographic projection of the first opening on the base substrate overlaps with an orthographic projection of the first electrode on the base substrate, and the first protection layer at least covers a side surface of the first electrode.

In the method for preparing the wiring substrate in the embodiments of the disclosure, the patterning process on the first protection layer to form the first openings exposing the first electrodes is performed in such a way that the first protection layer at least covers the side surface of the first electrode. That is, the first opening does not expose the entire area of the first electrode. By using smaller first openings to protect the side surface of the first electrode by the first protection layer, corrosion caused by moisture invading from the side surface of the first electrode can be avoided, thus preventing impacts on the yield of the wiring substrate.

In some embodiments, after performing the patterning process on the first protection layer to form the plurality of first openings that pass through the first protection layer along the thickness direction of the first protection layer, the method further includes: using an electroless plating process to form an anti-oxidation layer on a side of each first electrode facing away from the base substrate; where an orthographic projection of the anti-oxidation layer on the base substrate covers the orthographic projection of the first opening the base substrate.

In some embodiments, using the electroless plating process to form the anti-oxidation layer on the side of each first electrode facing away from the base substrate, specifically includes: using an Electroless Nickel Immersion Gold (ENIG) process to form the anti-oxidation layer. Specifically, a nickel layer is first grown on the side of the first electrode facing away from the base substrate, followed by growing a gold layer.

In some embodiments, after performing the patterning process on the first protection layer to form the plurality of first openings that pass through the first protection layer along the thickness direction of the first protection layer and before forming the anti-oxidation layer, the method further includes: forming a second protection layer on a side of the first protection layer facing away from the base substrate; performing a patterning process on the second protection layer to form a plurality of second openings that pass through the second protection layer along a thickness direction of the second protection layer; where the orthographic projection of the first electrode on the base substrate is located within an orthographic projection of the second opening on the base substrate.

In specific implementations, a mask used for performing the patterning process on the second protection layer to form the second opening is different from a mask used for performing the patterning process on the first protection layer to form the first opening.

In some embodiments, before performing the patterning process on the first protection layer to form the plurality of first openings passing through the first protection layer along the thickness direction of the first protection layer, the method further includes: forming a second protection layer on the side of the first protection layer facing away from the base substrate; performing the patterning process on the first protection layer to form the plurality of first openings passing through the first protection layer along the thickness direction of the first protection layer, specifically includes: performing a patterning process on both the second protection layer and the first protection layer to form the second openings passing through the second protection layer and the plurality of first openings passing through the first protection layer.

That is, after forming the first protection layer, the first openings are not formed immediately. After forming the second protection layer, in one patterning process, openings passing through both the second protection layer and the first protection layer are formed. These openings include both the first openings and second openings, as such one mask can be used to form both the first openings and second openings, saving costs.

In some embodiments, forming the plurality of first electrodes in the fan-out region of the base substrate, specifically includes: forming a third sub-layer in the fan-out region of the base substrate for the plurality of first electrodes; using a magnetron sputtering process to form a fourth sub-layer on the side of the third sub-layer facing away from the base substrate; and while performing the patterning process on the first protection layer to form the plurality of first openings passing through the first protection layer along the thickness direction of the first protection layer, removing the fourth sub-layer in regions of the first openings.

In some embodiments, before forming the plurality of first electrodes in the fan-out region of the base substrate, the method further includes:
forming a plurality of second electrodes in the fan-out region of the base substrate;
forming a pattern of a first insulating layer on a side of the plurality of second electrodes facing away from the base substrate; where the first insulating layer includes a plurality of third openings passing through the first insulating layer along the thickness direction of the first insulating layer; an orthographic projection of the third opening on the base substrate is located within the orthographic projection of the first electrode and the orthographic projection of the second electrode on the base substrate;
forming a pattern of a second insulating layer on a side of the first insulating layer facing away from the base substrate; where the orthographic projection of the third opening on the base substrate is located within an orthographic projection of the fourth opening on the base substrate, and the orthographic projection of the first electrode and the orthographic projection of the second electrode on the base substrate are located within the orthographic projection of the fourth opening on the base substrate.

In some embodiments, before forming the plurality of second electrodes in the fan-out region of the base substrate, the method further includes: forming a buffer layer.

In some embodiments, before forming the pattern of the first insulating layer on the side of the plurality of second electrodes facing away from the base substrate, the method further includes: forming a third insulating layer on the side of the plurality of second electrodes facing away from the base substrate.

In specific implementations, one patterning process can be used to form the third opening of the first insulating layer and the opening of the third insulating layer.

In some embodiments, after forming the pattern of the second insulating layer on the side of the first insulating layer facing away from the base substrate, and before forming the plurality of first electrodes, the method further includes: forming a pattern of a fourth insulating layer on the side of the second insulating layer facing away from the base substrate.

In some embodiments, while forming the plurality of second electrodes, the method further includes forming a pattern of the first sub-signal line; while forming the plurality of first electrodes, the method further includes: forming a pattern of the second sub-signal line, a first pad group, and a second pad group.

Embodiments of the disclosure provide a light-emitting substrate, as shown in FIG. 18. The light-emitting substrate includes the wiring substrate according to embodiments of the disclosure and light-emitting devices bonded to the wiring substrate.

In some embodiments, as shown in FIG. 18, the light-emitting substrate further includes a plurality of driver chips (ICs).

In some embodiments, based on that the wiring substrate includes a plurality of first pad groups and a plurality of second pad groups, the light-emitting devices are electrically connected to the first pad groups, and the driver chips are electrically connected to the second pad groups.

In specific implementations, the light-emitting device has two pins, and the two pins are electrically connected to a first pad and a second pad of the first pad group, respectively. The driver chip has a number of pins equal to the number of pads in the second pad group. For example, the driver chip has four pins, and the four pins are electrically connected to a ground pad, an output pad, an address pad, and a power pad.

In some embodiments, the light-emitting device is a micro-size inorganic electroluminescent device.

In specific implementations, the micro-size inorganic electroluminescent device may be a mini Light Emitting Diode (Mini-LED) or a micro Light Emitting Diode (Micro-LED). Mini-LEDs and Micro-LEDs are small in size and have high brightness, making them suitable for use in display devices or their backlight modules. For example, the typical size (e.g., length) of a Micro-LED is smaller than 100 microns, such as 10-80 microns; the typical size (e.g., length) of a Mini-LED is 80-350 microns, such as 80-120 microns. The light-emitting element may be at least one of Micro-LED or Mini-LED.

The light-emitting substrate according to the embodiments of the disclosure includes the wiring substrate according to embodiments of the disclosure, so the embodiment of this light-emitting substrate can refer to the above embodiments of the wiring substrate, and the details will not be repeated here.

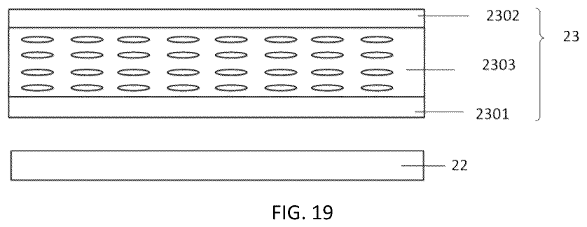

Embodiments of the disclosure provide a display apparatus, as shown in FIG. 19. The display apparatus includes the light-emitting substrate 22 according to embodiments of the disclosure.

In specific implementations, the light-emitting substrate can be applied in the display field. For example, the light-emitting substrate can serve as the backlight source of a display panel. As shown in FIG. 19, the display apparatus further includes a display panel 23 on a light-emitting side of the light-emitting substrate 22. The display panel 23 may be an LCD panel, including: an array substrate 2301 and an opposite substrate 2302 arranged opposite each other, and a liquid crystal layer 2303 located between the array substrate 2301 and the opposite substrate 2302.

The display apparatus according to embodiments of the disclosure includes the light-emitting substrate according to embodiments of the disclosure, so the implementation of this display apparatus can refer to the above embodiments for the wiring substrate, and the details will not be repeated here.

The display apparatus according to embodiments of the disclosure is a smartphone, tablet computer, television, monitor, laptop, digital photo frame, navigator, or any other device with a display function. The other essential components of the display apparatus are understood by those skilled in the art and will not be discussed here, and should not be considered as limitations of the disclosure.

In view of the above, in the wiring substrate, light-emitting substrate, and display apparatus according to the embodiments of the disclosure, the first protection layer covers at least the side surface of the first electrode. In this case, the first opening does not expose the entire region of the first electrode. By using a smaller first opening to protect the side surface of the first electrode with the first protection layer, the corrosion caused by moisture entering from the side surface of the first electrode can be prevented, thus avoiding a decrease in the yield of the wiring substrate.

Although the preferred embodiments of the invention have been described, those skilled in the art, upon learning the basic inventive concepts, can make further modifications and variations to these embodiments. Therefore, the appended claims are intended to be interpreted to include the preferred embodiments and all modifications and changes falling within the scope of the invention.

Apparently, those skilled in the art may make various modifications and variations to the disclosure without departing from the spirit and scope of the disclosure. Thus, if these modifications and variations fall within the scope of the claims and their equivalents, the disclosure is intended to include these modifications and variations.

1.-20. (canceled)

21. A wiring substrate, comprising:
a base substrate comprising a fan-out region;
a plurality of first electrodes on a side of the base substrate; and
a first protection layer on a side of the plurality of first electrodes facing away from the base substrate;
wherein the first protection layer comprising a plurality of first openings running through the first protection layer along a thickness direction of the first protection layer;
each of the plurality of first opening corresponds to one first electrode;
an orthographic projection of the first opening on the base substrate overlaps with an orthographic projection of the first electrode on the base substrate; and
the first protection layer at least covers a side surface of the first electrode.

22. The wiring substrate according to claim 21, wherein the orthographic projection of the first opening on the base substrate is located within the orthographic projection of the first electrode on the base substrate.

23. The wiring substrate according to claim 22, further comprising
a plurality of anti-oxidation layers on the side of the plurality of first electrodes facing away from the base substrate;
wherein each of the plurality of anti-oxidation layers is electrically connected to one of the plurality of first electrodes, and an orthographic projection of the anti-oxidation layer on the base substrate covers the orthographic projection of the first opening on the base substrate.

24. The wiring substrate according to claim 23, wherein the orthographic projection of the first opening on the base substrate is located within the orthographic projection of the anti-oxidation layer on the base substrate;
the orthographic projection of the anti-oxidation layer on the base substrate covers an orthographic projection of an edge, at the first opening, of the first protection layer on the base substrate.

25. The wiring substrate according to claim 24, further comprising:
a second protection layer on a side of the first protection layer facing away from the base substrate;
wherein the second protection layer comprises a second opening, and the orthographic projection of the first electrode on the base substrate is located within an orthographic projection of the second opening on the base substrate.

26. The wiring substrate according to claim 25, wherein the orthographic projection of the anti-oxidation layer on the base substrate is located within the orthographic projection of the second opening on the base substrate.

27. The wiring substrate according to claim 23, further comprising:
a second protection layer on a side of the first protection layer facing away from the base substrate;
wherein the second protection layer comprises a plurality of second openings running through the second protection layer along a thickness direction of the second protection layer;
an orthographic projection of the second opening on the base substrate is located within the orthographic projection of the first electrode on the base substrate.

28. The wiring substrate according to claim 27, wherein the plurality of second openings and the plurality of first openings are formed in a same patterning process.

29. The wiring substrate according to claim 28, wherein at the first opening and the second opening, the anti-oxidation layer cover a side surface of the first protection layer and a side surface of the second protection layer.

30. The wiring substrate according to claim 29, wherein at a contact position between the anti-oxidation layer and the second protection layer, a surface of the anti-oxidation layer facing away from the base substrate and a surface of the second protection layer facing away from the base substrate are in a same plane.

31. The wiring substrate according to claim 21, wherein the first electrode comprises a first surface facing away from the base substrate, and a distance between an edge of the first opening and an edge of the first surface of the first electrode is greater than or equal to 8 microns and less than or equal to 9 microns.

32. The wiring substrate according to claim 21, further comprising:
a plurality of second electrodes located in the fan-out region and disposed between the base substrate and the plurality of first electrodes, wherein each of the plurality of second electrodes is electrically connected to the first electrode, and an orthographic projection of the second electrode on the base substrate overlaps with the orthographic projection of the first electrode on the base substrate;
a first insulating layer located between the base substrate and the plurality of second electrodes, wherein the first insulating layer comprises a plurality of third openings running through the first insulating layer along a thickness direction of the first insulating layer, and an orthographic projection of the third opening is located within the orthographic projection of the first electrode on the base substrate, and within the orthographic projection of the second electrode on the base substrate; and
a second insulating layer located on a side of the first insulating layer facing away from the base substrate, wherein the second insulating layer comprises a plurality of fourth openings running through the second insulating layer along the thickness direction of the second insulating layer, the orthographic projection of the third opening on the base substrate is located within an orthographic projection of the fourth opening on the base substrate, the orthographic projection of the first electrode and the orthographic projection of the second electrode on the base substrate both are located within the orthographic projection of the fourth opening on the base substrate;
wherein the first electrode is electrically connected to the second electrode via the third opening and the fourth opening.

33. A method for preparing a wiring substrate, comprising:
providing a base substrate comprising a fan-out region;
forming a plurality of first electrodes in the fan-out region of the base substrate; and
forming a first protection layer on a side of the plurality of first electrodes facing away from the base substrate and performing a patterning process on the first protection layer to form a plurality of first openings running through the first protection layer along a thickness direction of the first protection layer;
wherein each of the plurality of first opening corresponds to one first electrode, and an orthographic projection of the first opening on the base substrate overlaps with an orthographic projection of the first electrode on the base substrate; and
the first protection layer at least covers a side surface of the first electrode.

34. The method according to claim 33, wherein after performing the patterning process on the first protection layer to form the plurality of first openings, the method further comprises:
using an electroless plating process to form an anti-oxidation layer on a side of each first electrode facing away from the base substrate;
wherein an orthographic projection of the anti-oxidation layer on the base substrate covers the orthographic projection of the first opening on the base substrate.

35. The method according to claim 34, wherein after performing the patterning process on the first protection layer to form the plurality of first openings running through the first protection layer along the thickness direction of the first protection layer and before forming the anti-oxidation layer, the method further comprises:
forming a second protection layer on a side of the first protection layer facing away from the base substrate; and
performing a patterning process on the second protection layer to form a second opening running through the second protection layer along a thickness direction of the second protection layer, wherein the orthographic projection of the first electrode on the base substrate is located within an orthographic projection of the second opening on the base substrate.

36. The method according to claim 34, wherein
before performing the patterning process on the first protection layer to form the plurality of first openings running through the first protection layer along the thickness direction of the first protection layer, the method further comprises:
forming a second protection layer on a side of the first protection layer facing away from the base substrate;
the performing the patterning process on the first protection layer to form the plurality of first openings running through the first protection layer along the thickness direction of the first protection layer, comprises:
performing a patterning process on the first protection layer and the second protection layer to form the plurality of first openings running through the first protection layer along the thickness direction of the first protection layer and a plurality of second openings running through the second protection layer along the thickness direction of the second protection layer.

37. The method according to claim 33, wherein before forming the plurality of first electrodes in the fan-out region of the base substrate, the method further comprises:
forming a plurality of second electrodes in the fan-out region of the base substrate;
forming a pattern of a first insulating layer on a side of the plurality of second electrodes facing away from the base substrate, wherein the first insulating layer comprises a plurality of third openings running through the first insulating layer along a thickness direction of the first insulating layer, and an orthographic projection of the third opening on the base substrate being located within the orthographic projection of the first electrode on the base substrate and within an orthographic projection of the second electrode on the base substrate; and
forming a second insulating layer on a side of the first insulating layer facing away from the base substrate, wherein the second insulating layer comprises a plurality of fourth openings running through the second insulating layer along a thickness direction of the second insulating layer, the orthographic projection of the third opening on the base substrate is located within an orthographic projection of the fourth opening on the base substrate, and the orthographic projection of the first electrode and the orthographic projection of the second electrode on the base substrate both are located within the orthographic projection of the fourth opening on the base substrate.

38. A light-emitting substrate, comprising:
the wiring substrate according to claim 21; and
light-emitting devices bonded to the wiring substrate.

39. The light-emitting substrate according to claim 38, wherein the light-emitting devices are micro-sized inorganic electroluminescent devices.

40. A display apparatus, comprising the light-emitting substrate according to claim 38.
